(19) United States
(12) Patent Application Publication
(10) Pub. No.: US 2026/0110709 A1
(43) Pub. Date: Apr. 23, 2026

(54) Test Socket for Enhancing Integrated Circuit Chip Testing and a Manufacturing Method Thereof

(71) Applicant: He Chou Technology INC., Hsinchu City (TW)

(72) Inventors: Wei-Been Yu, Hsinchu City (TW); Shao-Chun Tseng, Hsinchu City (TW)

(21) Appl. No.: 19/170,098

(22) Filed: Apr. 4, 2025

(30) Foreign Application Priority Data
Apr. 24, 2024 (TW) 113115336

(51) Int. Cl. G01R 1/04; G01R 3/00; G01R 31/28

(52) U.S. Cl. CPC G01R 1/0466; G01R 3/00; G01R 31/2863; G01R 1/0483

(57) ABSTRACT

A test socket for testing integrated circuit (IC) chips and a manufacturing method for the test socket are disclosed. The test socket comprises an insulating support structure having a plurality of through holes and a plurality of elastic conductive posts. The conductive posts are partially embedded in the support structure and extend through the through holes to accommodate variations due to IC package warpage and ball grid array (BGA) solder ball size tolerances. The insulating support structure further includes grooves adjacent to the through holes to securely fasten the conductive posts. Each conductive post features an elastic structure with at least a portion of its circumferential surface covered by an insulating material layer to prevent short circuits. The test socket further comprises a rigid support frame—potentially made of polyimide, PCB material, or ceramic—and a soft support frame made of silicone, which is both durable and flexible.

### FIELD OF THE DISCLOSURE

The present invention relates to the semiconductor manufacturing field and, more specifically, to a test socket used for electrical testing of integrated circuit chips.

### BACKGROUND OF THE INVENTION

In the field of electronics manufacturing, testing IC chips is a critical step to ensure the functionality and reliability of the components prior to their deployment in consumer products. Test sockets play a key role in this process by temporarily connecting the IC chips to test equipment, thereby allowing the performance of the IC to be evaluated without permanent soldering.

A primary challenge in designing test sockets is to balance reliable electrical contact with the ability to accommodate various IC chip sizes and configurations. Conventional test sockets often rely on rigid conductive elements that may not adapt well to changes in IC package dimensions or the presence of warpage. Furthermore, maintaining the integrity of electrical contact while preventing short circuits between densely arranged conductive elements remains a persistent problem.

Another important concern is the durability and reliability of the test socket itself. Frequent insertion and removal of IC chips may wear the socket's components, potentially leading to inaccurate test results or the need for frequent replacement. The materials used in the construction of the test socket—including the support structure and the conductive elements—are critical to its overall performance and lifespan.

In view of these challenges, it is apparent that one of ordinary skill in the art would continually seek to innovate test socket designs to provide improved flexibility, reliability, and ease of use.

### SUMMARY OF THE INVENTION

In order to overcome the above problems, the present invention provides a test socket for enhancing IC chip testing and a manufacturing method thereof. In one aspect, the invention relates to a test socket specifically designed for IC chip testing, combining an advanced structural configuration with a specific manufacturing method. The invention aims to significantly improve the reliability and efficiency of IC chip testing through its unique features.

The test socket comprises an insulating support structure that includes a plurality of through holes. A number of elastic conductive posts are embedded within the support structure and extend through the through holes. Each conductive post comprises a first portion located beneath the insulating support structure and a second portion located above the insulating support structure. A unique feature of the conductive posts is that at least a portion of their circumferential surfaces is covered by an insulating material layer, which is designed to prevent electrical short circuits and ensure stable and reliable electrical contact during testing.

A key innovation of the test socket is its use of specific materials and structural components. The insulating support structure includes both a rigid support frame and a soft support frame. The rigid support frame is fabricated from materials such as polyimide, PCB material, or ceramic, providing the necessary structural rigidity and durability. In contrast, the soft support frame is made of silicone, which offers the flexibility required to accommodate variations arising from IC package warpage or BGA solder ball size tolerances.

Furthermore, the insulating support structure is provided with a plurality of grooves adjacent to the through holes. These grooves help secure the conductive posts within the structure, thereby enhancing the durability of the test socket.

The manufacturing method of the test socket involves forming a layered structure comprising at least one insulating support layer and at least one sacrificial layer. The method includes forming a first set of through holes in the layered structure, filling these holes with an insulating material, and then forming a second set of through holes within the insulating material. Conductive gel is then injected into the second through holes to form the elastic conductive posts. Finally, the sacrificial layer is removed to expose the conductive posts and the insulating support structure, yielding a test socket for IC chip testing.

Thus, the present invention provides a reliable, flexible, and durable solution for IC chip testing by overcoming issues such as potential short circuits or leakage that may occur when the conductive posts deform under pressure during testing.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1A is a partial cross-sectional view of a test socket according to one embodiment of the present invention.

FIG. 1B and FIG. 1C illustrate deformations of the embodiment shown in FIG. 1A.

FIG. 2A is a partial cross-sectional view of another embodiment of a test socket according to the present invention.

FIGS. 2B to 2D illustrate deformations of the embodiment shown in FIG. 2A.

FIG. 3 is a flowchart of one embodiment of the manufacturing method for the test socket.

FIGS. 4A to 4F are schematic diagrams of the test socket at various stages of the manufacturing method, each corresponding to the steps outlined in FIG. 3.

FIG. 5 is a flowchart of another embodiment of the manufacturing method for the test socket.

FIGS. 6A and 6B are schematic diagrams illustrating additional stages of the manufacturing method for the test socket as shown in FIG. 5.

### DESCRIPTION OF THE PREFERRED EMBODIMENTS

The present invention relates to a test socket specifically designed for testing integrated circuit (IC) chips. In the electronics field, test sockets establish a reliable electrical connection between the IC chip and test equipment during the evaluation phase. This temporary connection must be precise and stable in order to ensure accurate test results without the need for permanent soldering, which is critical for both the efficiency and cost-effectiveness of IC chip testing.

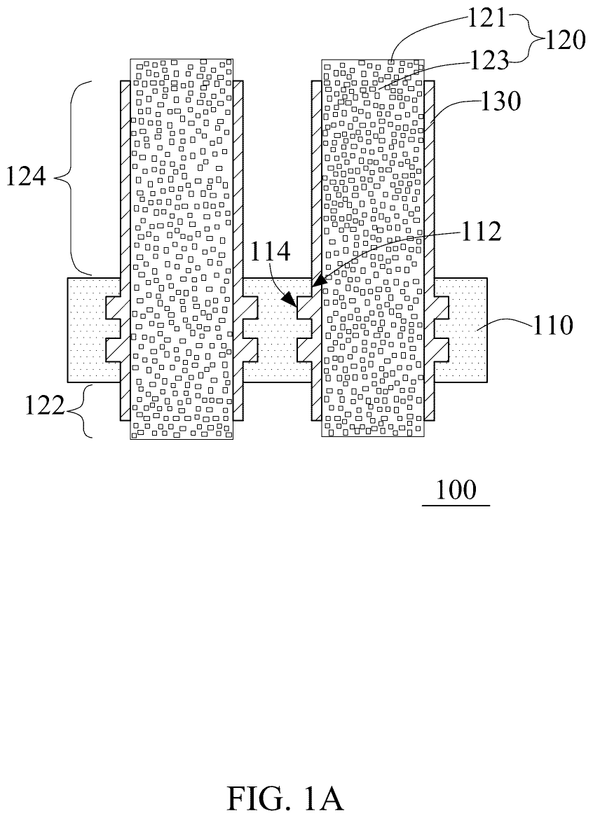

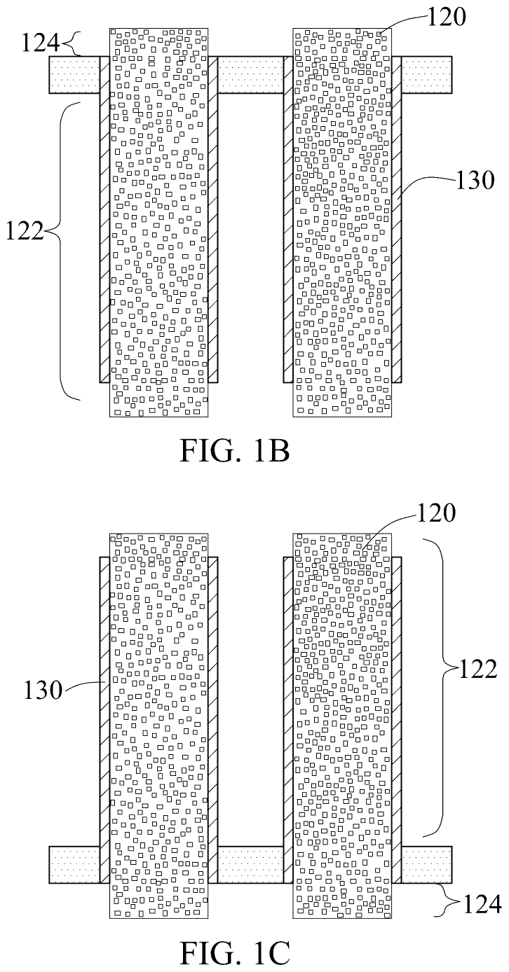

Referring now to FIG. 1A, a partial cross-sectional view of a test socket 100 according to one embodiment of the present invention is shown. One of the main features of the test socket 100 disclosed in this embodiment is an insulating support structure 110, which is provided with a plurality of through holes 112. Elastic conductive posts 120 are embedded within the insulating support structure 110 and extend through the through holes 112. In this embodiment, a portion of each elastic conductive post 120 is located below the insulating support structure 110 (hereinafter referred to as the first portion 122), and another portion is located above the insulating support structure 110 (hereinafter referred to as the second portion 124). Additionally, each elastic conductive post 120 further includes a third portion 126 within the insulating support structure 110, wherein the upper and lower ends of the third portion 126 are respectively connected to the corresponding ends of the second portion 124 and the first portion 122.

Moreover, the insulating support structure 110 is further provided with grooves 114 adjacent to the through holes 112. These grooves 114 accommodate portions of the elastic conductive posts 120, thereby ensuring stable attachment between the elastic conductive posts 120 and the insulating support structure 110, which in turn enhances the durability of the test socket 100 during testing.

In the illustrated embodiment, each elastic conductive post 120 comprises conductive particles 121 and an elastic material 123, for example, a silicone-based material. The conductive particles 121 ensure the conductivity of the elastic conductive post 120, while the elastic material 123 not only provides the necessary elasticity but also aids in the overall stability of the connection by adhering to the grooves 114 adjacent to the through holes 112.

Furthermore, at least a portion of the circumferential surface of the elastic conductive posts 120 is covered by an insulating material layer 130, which significantly reduces the risk of short circuits during testing, particularly when the elastic conductive posts 120 are deformed under pressure. In this embodiment, the thickness of the insulating material layer 130 may range from 50 to 500 micrometers. The position of the insulating material layer 130 on the elastic conductive posts 120 may vary according to different designs. For instance, as shown in FIG. 1B, the insulating material layer 130 may be located on the first portion 122 and the third portion 126 (situated below the insulating support structure 110), or, as illustrated in FIG. 1C, the insulating material layer 130 may be located on the second portion 124 and the third portion 126 (situated above the insulating support structure 110). In the present embodiment, the insulating material layer 130 is made of silicone, which is noted for its excellent thermal stability and electrical insulation properties.

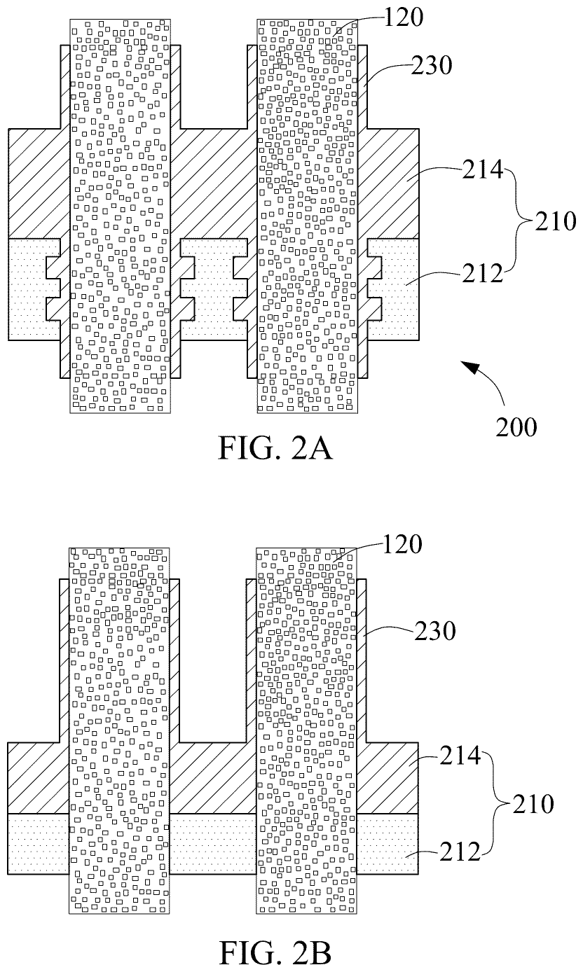

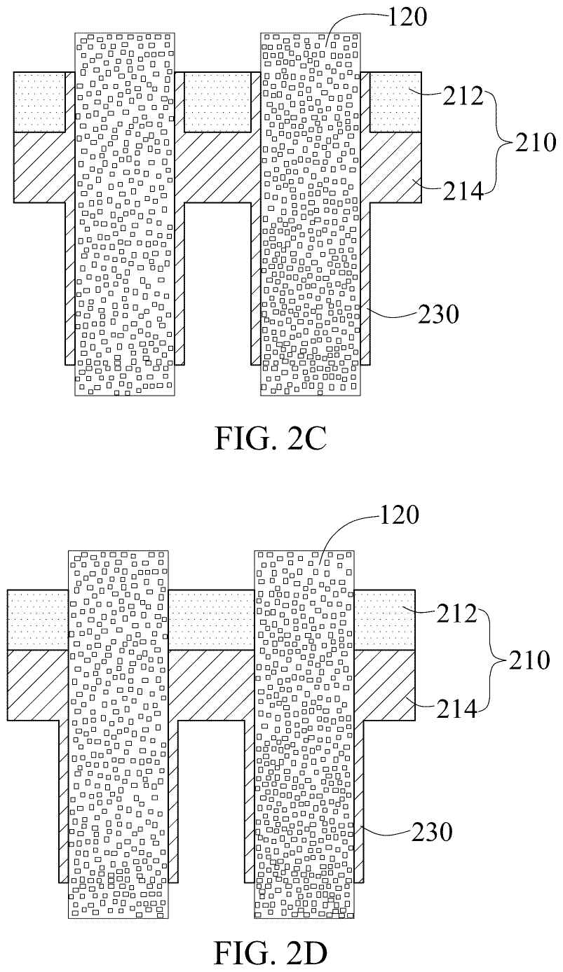

Referring now to FIG. 2A, a partial cross-sectional view of another embodiment of a test socket 200 is shown. In this embodiment, the insulating support structure 210 comprises a rigid support frame 212 and a soft support frame 214. The rigid support frame 212 provides overall stiffness and durability to the insulating support structure 210, while the soft support frame 214 provides the necessary flexibility to accommodate changes induced by external factors such as IC package warpage or variations in BGA solder ball sizes.

In this embodiment, the rigid support frame 212 of the insulating support structure 210 is made of high-rigidity, high-durability materials such as polyimide, PCB material, or ceramic. Polyimide is well known for its excellent thermal stability, electrical insulation, and mechanical strength, whereas PCB and ceramic materials offer robustness and durability, thereby extending the lifespan of the test socket 200.

The soft support frame 214 is positioned above the rigid support frame 212 and is generally made of a softer material, such as silicone, which is capable of providing adaptable support for the elastic conductive posts 120 that may move or deform during testing.

In this embodiment, the insulating material layer 230 may be selectively applied to various portions of the elastic conductive posts 120. For example, as shown in FIG. 2B, the top peripheral region of the elastic conductive post 120 may not be fully covered by the insulating material layer 230. Alternatively, as shown in FIG. 2C, when the soft support frame 214 is positioned below the rigid support frame 212, the insulating material layer 230 may be applied not only to the portion of the elastic conductive post 120 adjacent to the upper part of the soft support frame 214 but also to the portion within the rigid support frame 212, leaving only the bottom periphery of the elastic conductive post 120 exposed. In another alternative, as shown in FIG. 2D, the soft support frame 214 may be positioned below the rigid support frame 212, with the insulating material layer 230 applied only to the lower portion of the elastic conductive post 120 adjacent to the soft support frame 214, without fully covering the top and bottom peripheries of the elastic conductive post 120.

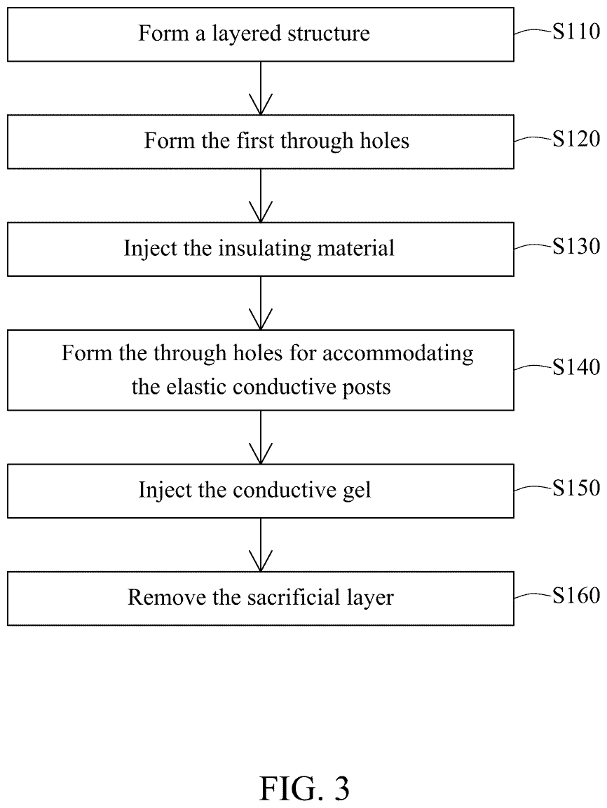

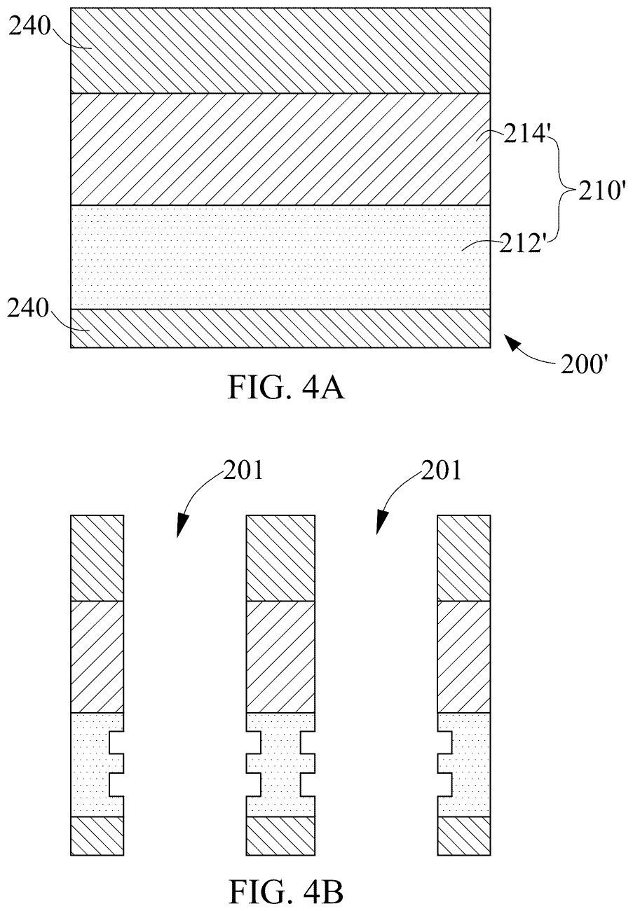

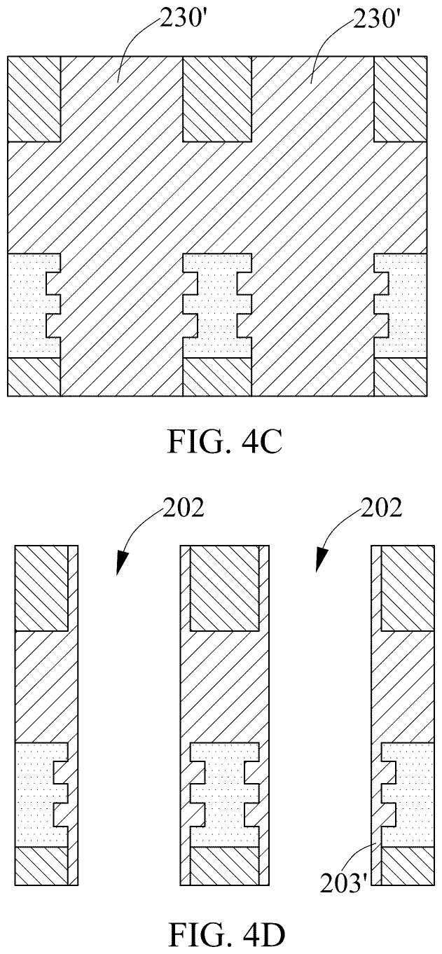

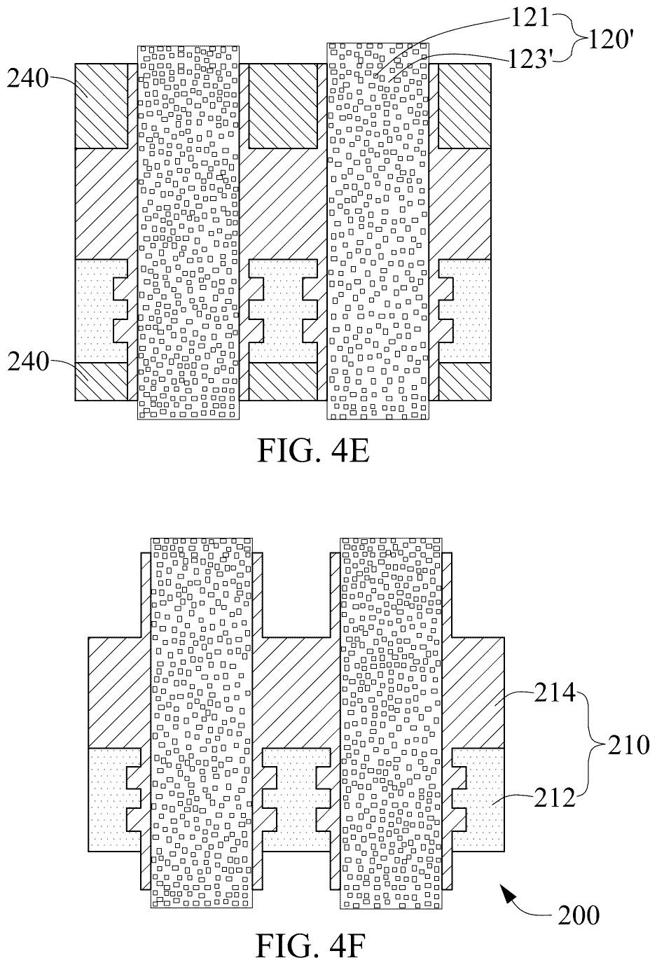

Next, referring to FIG. 3 in conjunction with FIGS. 4A to 4F, a flowchart of one embodiment of the manufacturing method for the test socket is provided, with FIGS. 4A to 4F being schematic diagrams of the test socket at various stages corresponding to the steps outlined in FIG. 3. First, referring to step S110 and FIG. 4A, a layered structure 200′ is formed to serve as the molding base for the test socket 200. The layered structure 200′ comprises an insulating support layer 210′ and at least one sacrificial layer 240 (in FIG. 4A, a two-layer sacrificial layer 240 is shown), wherein the insulating support layer 210′ provides the necessary physical and electrical insulation for testing, and the sacrificial layer 240 is subsequently removed. In this embodiment, the insulating support layer 210′ includes a rigid support layer 212′ and a soft support layer 214′. The sacrificial layer 240 is selected for its ease of removal by either mechanical means or chemical means, without damaging the insulating support layer 210′ or the conductive posts 120.

Then, referring to step S120 and FIG. 4B, a plurality of first through holes 201 are formed in the layered structure 200′. The locations of the first through holes 201 are determined by the final positions of the elastic conductive posts 120, and they are precisely formed using machining tools such as laser cutters, micro-drilling machines, etching equipment, or CNC machining.

Next, referring to step S130 and FIG. 4C, an insulating material 230′ is injected to fill the first through holes 201. In this embodiment, the insulating material 230′ is silicone, although those skilled in the art will recognize that other types of insulating materials may be used. Subsequently, referring to step S140 and FIG. 4D, a second set of through holes 202 is formed in the insulating material 230′. These second through holes 202, which are formed within the insulating material 230′, serve as the locations for filling conductive gel 120′ to form the elastic conductive posts 120.

Then, referring to step S150 and FIG. 4E, conductive gel 120′ is injected into the second through holes 202. The conductive gel 120′ is a mixture of conductive particles 121 and an adhesive 123′ (for example, a silicone-based adhesive), which, upon curing, forms the elastic material 123 as shown in FIG. 2A, thereby forming the elastic conductive posts 120. It is preferable in this step to inject the conductive gel 120′ into each of the second through holes 202 in a vacuum environment to avoid air bubbles and ensure consistent performance of the elastic conductive posts 120.

Next, referring to step S160 and FIG. 4F, the sacrificial layer 240 is removed. The sacrificial layer 240 can be removed by various methods, such as peeling or chemical dissolution, depending on the material of the sacrificial layer 240. Removing the sacrificial layer 240 exposes portions of the elastic conductive posts 120, which are now securely embedded in the insulating support structure 230.

It should be noted that although the manufacturing method shown in FIG. 3 is used for producing the test socket 200 as illustrated in FIG. 2, those skilled in the art will recognize that by adjusting the steps of the manufacturing method, test sockets according to other embodiments may be produced. For example, referring again to FIG. 4A, if the insulating support layer 210′ comprises only a rigid support layer 212′ without a soft support layer 214′, a test socket similar to that shown in FIG. 1A (test socket 100) may be formed.

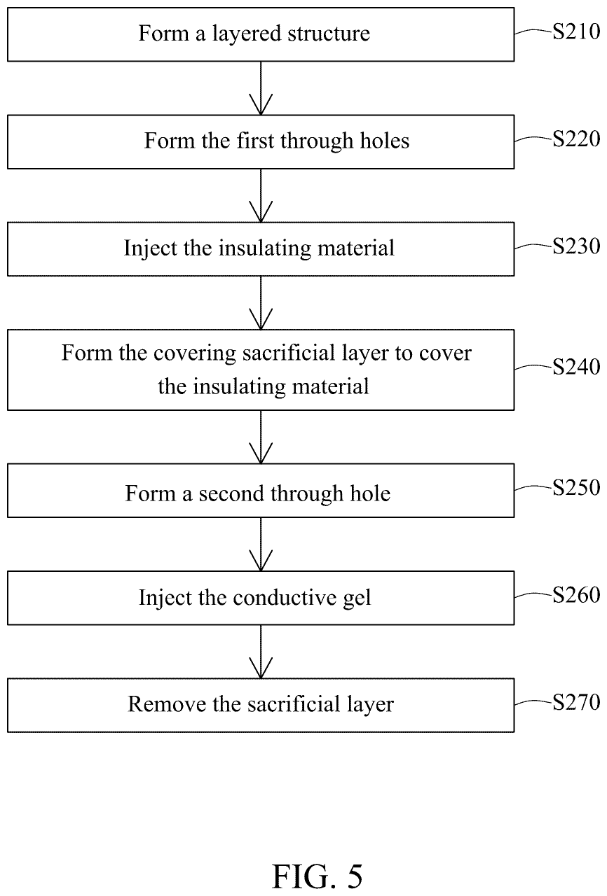

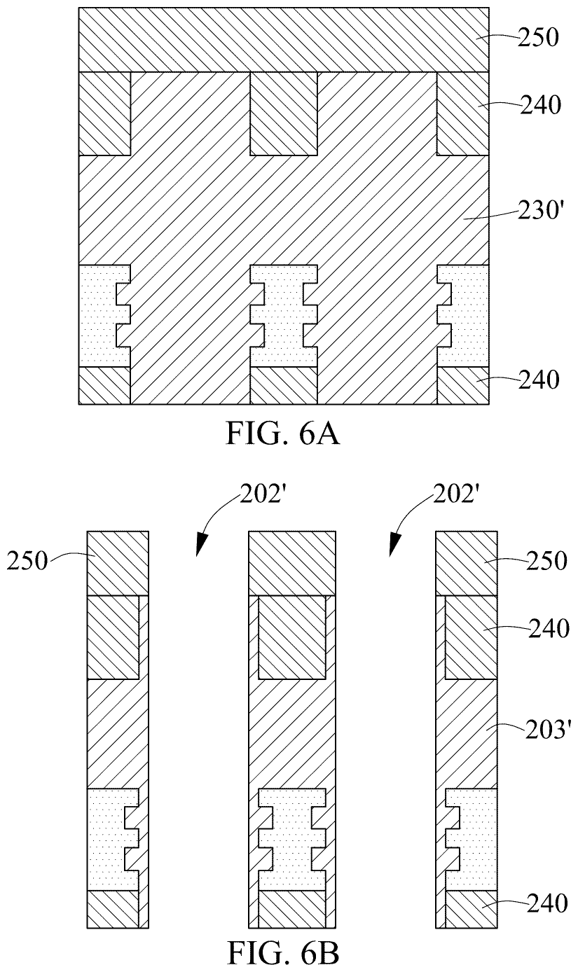

Alternatively, referring to FIG. 5 and FIGS. 6A and 6B, FIG. 5 is a flowchart of another embodiment of the manufacturing method for the test socket, and FIGS. 6A and 6B are schematic diagrams illustrating additional stages of the manufacturing method corresponding to the new steps shown in FIG. 5. In FIG. 5, steps S210 to S230 are identical to steps S110 to S130 and therefore will not be repeated herein. Next, referring to step S240 and FIG. 6A, after the insulating material 230′ is filled, a covering sacrificial layer 250 is formed to cover the insulating material 230′. In this embodiment, the covering sacrificial layer 250 is made of the same material as the sacrificial layer 240. Thereafter, referring to step S250 and FIG. 6B, a second set of through holes 202′ is formed, wherein the second through holes 202′ extend through both the insulating material 230′ and the covering sacrificial layer 250. The subsequent steps S260 and S270 correspond to steps S150 and S160 in FIG. 3, and therefore are not described in further detail. Following the manufacturing process from step S210 through step S270, a test socket similar to the one shown in FIGS. 2B to 2D is obtained, for example, a test socket in which the top of the elastic conductive posts 120 is not covered by the insulating material layer 230, as illustrated in FIG. 2B.

Furthermore, by using a manufacturing process similar to steps S210 through S270, test sockets corresponding to those shown in FIGS. 2C to 2D can also be produced. For example (description provided in text only, without corresponding drawings), to produce a test socket as shown in FIG. 2D, a layered structure is first formed with a soft support layer 214 positioned above a first sacrificial layer, followed by the formation of the first through holes. After the insulating material is injected into the first through holes, a rigid support layer 212 and a second sacrificial layer are formed on top of the rigid support layer 212, and a third sacrificial layer is then applied below the first sacrificial layer. Subsequently, a second through hole is formed within the first through hole, conductive gel 120 is filled and cured, and finally all sacrificial layers are removed, yielding the test socket shown in FIG. 2D.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

1. A test socket for testing integrated circuit (IC) chips, comprising:
an insulating support structure having a plurality of through holes; and
a plurality of elastic conductive posts embedded in the insulating support structure and extending through the plurality of through holes;
wherein each of the elastic conductive posts comprises a first portion located below the insulating support structure and a second portion located above the insulating support structure; and
wherein at least a portion of the circumferential surface of the elastic conductive posts is covered by an insulating material layer.

2. The test socket of claim 1, wherein the thickness of the insulating material layer is between 50 and 500 micrometers.

3. The test socket of claim 1, wherein the insulating material layer is located on the first portion of the elastic conductive posts.

4. The test socket of claim 1, wherein the insulating material layer is located on the second portion of the elastic conductive posts.

5. The test socket of claim 1, wherein the insulating material layer is located on both the first and second portions of the elastic conductive posts.

6. The test socket of claim 1, wherein the insulating material is silicone.

7. The test socket of claim 1, wherein the insulating support structure comprises a rigid support frame and a soft support frame.

8. The test socket of claim 7, wherein the rigid support frame is made of a material selected from the group consisting of polyimide, PCB material, and ceramic.

9. The test socket of claim 7, wherein the soft support frame is made of silicone.

10. The test socket of claim 1, wherein the insulating support structure further comprises a plurality of grooves located adjacent to the through holes, wherein a portion of the conductive posts is embedded within the grooves.

11. A manufacturing method for a test socket for testing integrated circuit (IC) chips, comprising the steps of:
forming a layered structure comprising at least one insulating support layer and at least one sacrificial layer;
forming a plurality of first through holes in the layered structure;
filling the first through holes with an insulating material;
forming a plurality of second through holes in the insulating material;
filling the second through holes with a conductive gel to form a plurality of elastic conductive posts; and
removing the sacrificial layer from the layered structure.

12. The method of claim 11, further comprising the step of forming a covering sacrificial layer to cover the insulating material after filling the first through holes.

13. The method of claim 12, wherein the second through holes are also formed in the covering sacrificial layer, and the second through holes extend through both the covering sacrificial layer and the insulating material.

14. The method of claim 11, wherein the sacrificial layer is removed by a peeling process.

15. The method of claim 11, wherein the sacrificial layer is removed by dissolving it in a solvent.
